(19) United States
(12) Patent Application Publication
(10) Pub. No.: US 2005/0145900 A1
(43) Pub. Date: Jul. 7, 2005

(54) Charge sweep operation for reducing image lag

(76) Inventor: Howard E. Rhodes, Boise, ID (US)

Correspondence Address: DICKSTEIN SHAPIRO MORIN & OSHINSKY LLP, 2101 L Street, NW, Washington, DC, 20037, US

(21) Appl. No.: 10/750,843

(22) Filed: Jan. 5, 2004

(51) Int. Cl. H01L 31/062; H01L 21/00

(52) U.S. Cl. 257/290; 257/291; 438/48

(57) ABSTRACT

A method and apparatus are disclosed for improving imager lag by using a charge sweep operation in which residual charge is swept out of the photodiode to reduce lag effects. The charge is swept out of the photodiode by activating the reset transistor a second time, substantially simultaneously with the activation of the transfer gate after the signal voltage V_{sig} is readout. A second embodiment sweeps charge out of the photodiode by activating a transistor electrically connected to the photodiode after the signal voltage V_{sig} is readout.

### FIELD OF THE INVENTION

The invention relates generally to a method and apparatus for reducing image lag in a pixel array image sensor.

### BACKGROUND

Typically, a digital imager array includes a focal plane array of pixel cells, each one of the cells including a photoconversion device, e.g. a photogate, photoconductor, or a photodiode. In a complementary metal oxide semiconductor (CMOS) imager a readout circuit is connected to each pixel cell which typically includes a source follower output transistor. The photoconversion device converts photons to electrons which are typically stored at a floating diffusion region connected to the gate of the source follower output transistor. A charge transfer device (e.g., transistor) can be included for transferring charge from the photoconversion device to the floating diffusion region. In addition, such imager cells typically have a transistor for resetting the floating diffusion region to a predetermined charge level prior to charge transference. The output of the source follower transistor is gated as an output signal by a row select transistor.

Exemplary CMOS imaging circuits, processing steps thereof, and detailed descriptions of the functions of various CMOS elements of an imaging circuit are described, for example, in U.S. Pat. No. 6,140,630 to Rhodes, U.S. Pat. No. 6,376,868 to Rhodes, U.S. Pat. No. 6,310,366 to Rhodes et al., U.S. Pat. No. 6,326,652 to Rhodes, U.S. Pat. No. 6,204,524 to Rhodes, and U.S. Pat. No. 6,333,205 to Rhodes. The disclosures of each of the forgoing patents are herein incorporated by reference in their entirety.

FIG. 1 shows one example of a pixel cell of a typical CMOS imager. A photodiode 49 is comprised of regions 21, 23 which are opposite doping types, creating a p-n junction. When incident light strikes the photodiode 49, electron/hole pairs are generated in the p-n junction of the photoconversion 49. The generated electrons are collected in the n-type region 23 of the photodiode 49. The photo charge moves from the initial charge accumulation region to a charge collection region, typically a floating diffusion region 17, or it may be transferred to floating diffusion region 17 via a transfer transistor 27. The charge at floating diffusion region 17 is typically converted to a pixel output voltage by a source follower transistor 41.

FIG. 2 illustrates a typical simplified timing diagram for the signals used to transfer charge out of the pixel cell of FIG. 1. The row select transistor 43 is activated by signal RS and connects the pixel to a column line 32. The reset transistor 29 is typically turned on by signal Reset and the floating diffusion region 17 is reset to a predetermined voltage (e.g. V_{dd}). The resulting reset voltage (Vᵣₛₜ) produced by transistor 41 is captured in sample and hold circuitry 35 in response to a reset sample and hold signal SHR. Integration of light and collection of electrons at photodiode 49 is conducted at least during the reset period and prior to the application of a transfer gate TG voltage signal. The transfer gate voltage signal (TG) is then applied to the gate of the transfer transistor to cause the charge in the photodiode 49 to transfer to the floating diffusion region 17. The resulting signal output voltage (V_{sig}) produced by transistor 41 is then sampled by the sample and hold circuitry 35 in response to sample and hold signal SHS.

FIG. 3 is a potential energy diagram for a typical CMOS imager undergoing a charge transfer from the photodiode 49 to the floating diffusion region 17 and illustrates a typical image lag problem. FIG. 3a shows a first stage in the transfer process in which the photodiode 49 is filled with collected charge (shown as shaded area) from exposure to light. At this point, the transfer gate is off. When the transfer gate 27 is turned on, as shown in FIG. 3b, charge collected in the photodiode 49 is transferred to the floating diffusion region 17. When the transfer gate 27 is turned off again, as shown in FIG. 3c, some charge remains in the photodiode 49 that was not transferred to the FD 17 in step 3b. The remaining charge becomes a lag signal in the subsequent frame as it combines with charge from the next frame.

Charge remaining in the pixel from a prior image can affect a subsequent image, causing a ghost image from the residual charge to appear in a subsequent image. Incomplete charge transfer reduces the charge transfer efficiency (CTE) of the pixel cell. Image lag can occur, for example, in CMOS image sensor pixels having transfer transistors for transferring charge from the photodiode 49 to the floating diffusion region 17. In a 4-transistor (4T) or 5-transistor (5T) circuit, image lag can be caused in part when the charge capacity of the photodiode 49 is larger than the charge storage capacity of the floating diffusion region 17. One way to address the charge disparity is to reduce capacity of the photodiode, however, when this is done, the pixel output signal is also reduced.

There also can be other mechanisms that leave residual charge in the photodiode such as the presence of potential barriers and wells. In all cases, it is advantageous to clear as much charge out of the photodiode as possible. Therefore, it is desirable to have an imager with reduced image lag without sacrificing image output signal levels.

### SUMMARY

Exemplary embodiments of the invention provide a method and apparatus for improving imager lag by using a charge sweep operation in which residual charge is swept out of the photodiode to reduce lag effects. The charge is swept out of the photodiode by turning on the reset gate a second time, substantially simultaneously with the activation of the transfer gate after the signal voltage (V_{sig}) is read. A second embodiment sweeps charge out of the photodiode by activating a transistor electrically connected to the photodiode after the signal voltage V_{sig} is readout.

### BRIEF DESCRIPTION OF THE DRAWINGS

The above and other features and advantages of the invention will be more readily understood from the following detailed description which is provided in connection with the accompanying drawings in which:

FIG. 1 illustrates a conventional pixel sensor cell;

FIG. 2 is a timing diagram illustrating operation of the FIG. 1 pixel cell;

FIG. 3 is a potential energy diagram of the FIG. 1 pixel cell;

FIG. 4 is a top view of a pixel cell operated in accordance with an exemplary embodiment of the invention;

FIG. 5 illustrates a pixel cell operated in accordance with an exemplary embodiment of the invention;

FIGS. 6a-c are timing diagrams illustrating exemplary operations of the FIG. 5 pixel cell according to embodiments of the invention;

FIGS. 7a-d are detailed views showing timing of selected gate transistors according to embodiments of the invention;

FIGS. 8a-d are potential energy diagrams of the FIG. 5 pixel cell operated in accordance with an exemplary embodiment of the invention;

FIG. 9 is a top view of a pixel cell operated in accordance with an exemplary embodiment of the invention;

FIG. 10 illustrates a pixel cell operated in accordance with an exemplary embodiment of the invention;

FIG. 11 is a timing diagram illustrating exemplary operations of the FIG. 10 pixel cell according to an embodiment of the invention;

FIG. 12 is a block diagram of an imager device employing an array of pixel cells operated in accordance with an exemplary embodiment of the invention; and

FIG. 13 is a schematic diagram of a processing system employing an imager device operated in accordance with an exemplary embodiment of the invention.

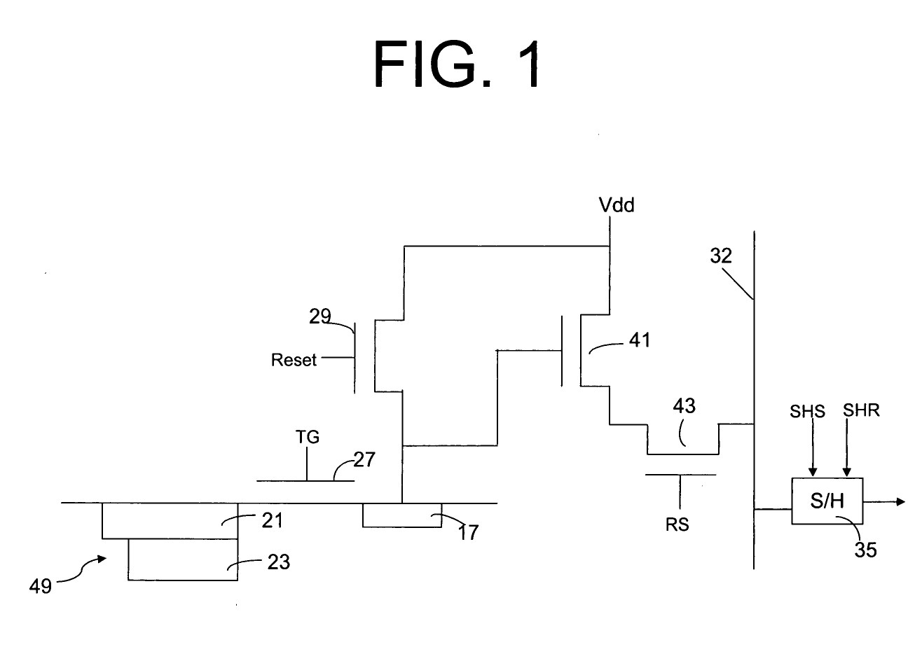

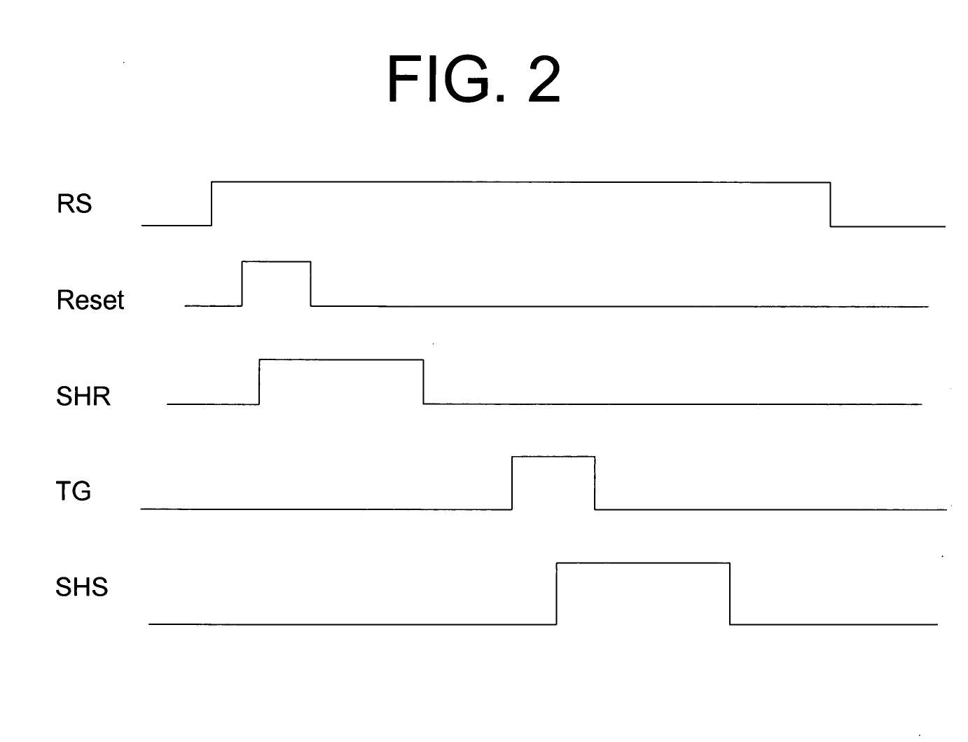

### DETAILED DESCRIPTION OF THE INVENTION

In the following detailed description, reference is made to the accompanying drawings, which form a part hereof and show by way of illustration specific exemplary embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order.

The terms “wafer” and “substrate,” as used herein, are to be understood as including silicon, silicon-on-insulator (SOI) or silicon-on-sapphire (SOS) technology, doped and undoped semiconductors, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor need not be silicon-based, but could be based on silicon-germanium, germanium, gallium arsenide or other semiconductors.

The term “pixel,” as used herein, refers to a photo-element unit cell containing a photoconversion device and associated transistors for converting photons to an electrical signal. The pixels discussed herein are illustrated and described as inventive modifications to four transistor (4T) pixel circuits for the sake of example only. It should be understood that the invention may be used with other pixel arrangements having more than four transistors (e.g., 5T, 6T, 7T). Although the invention is described herein with reference to the architecture and fabrication of one pixel, it should be understood that this is representative of a plurality of pixels in an array of an imager device. The following detailed description is, therefore, not to be taken in a limiting sense.

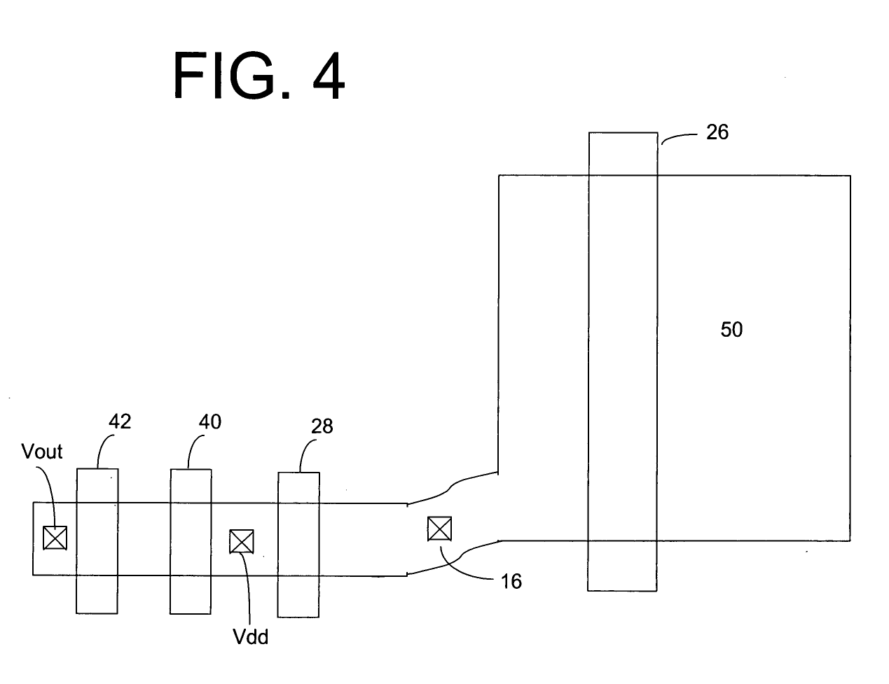

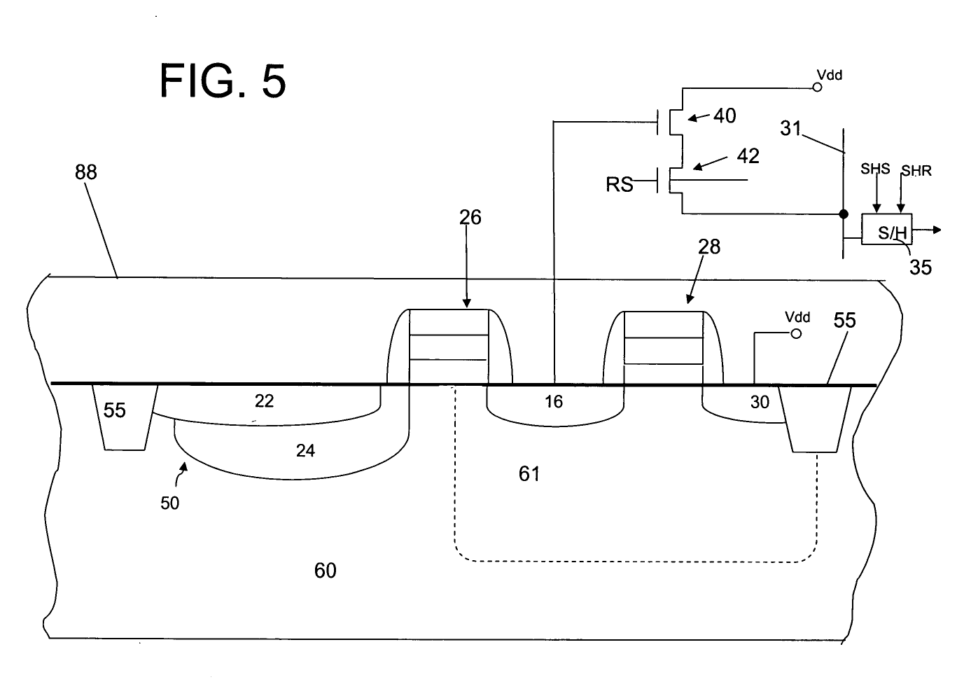

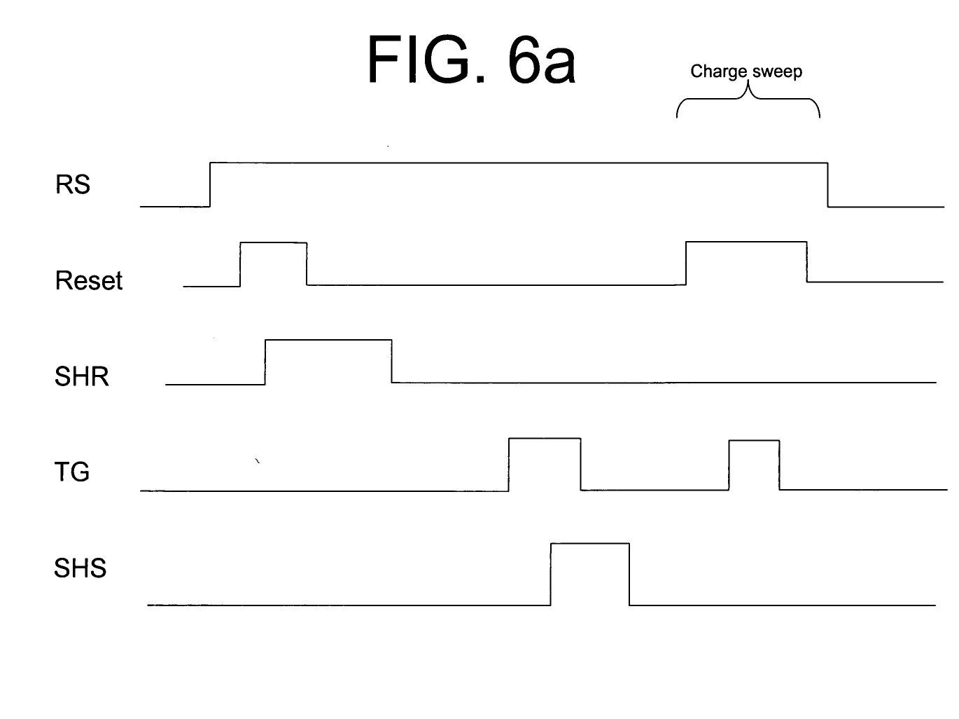

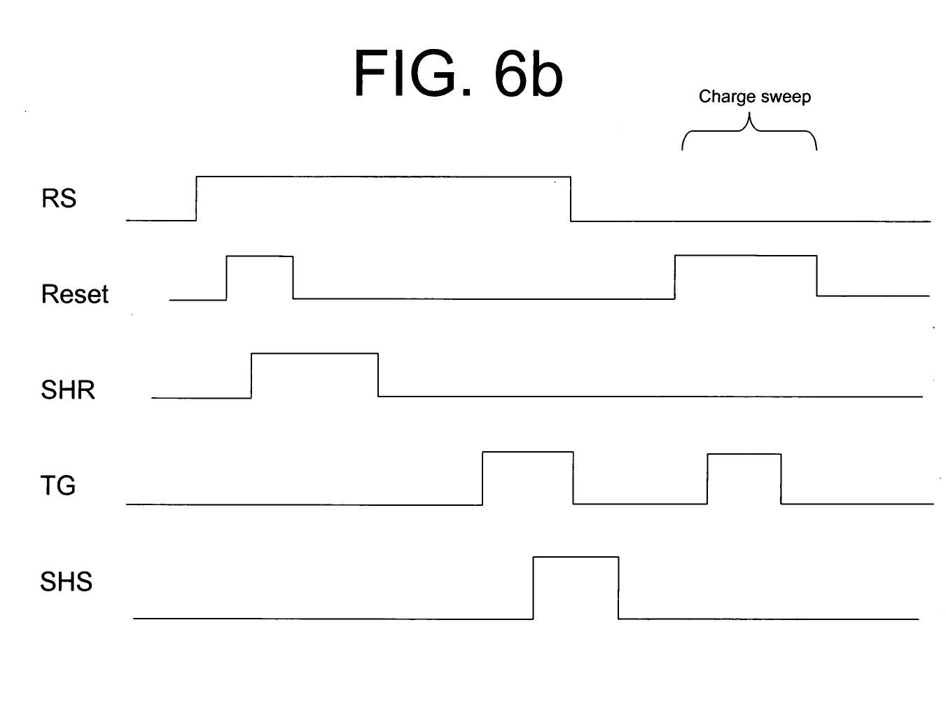

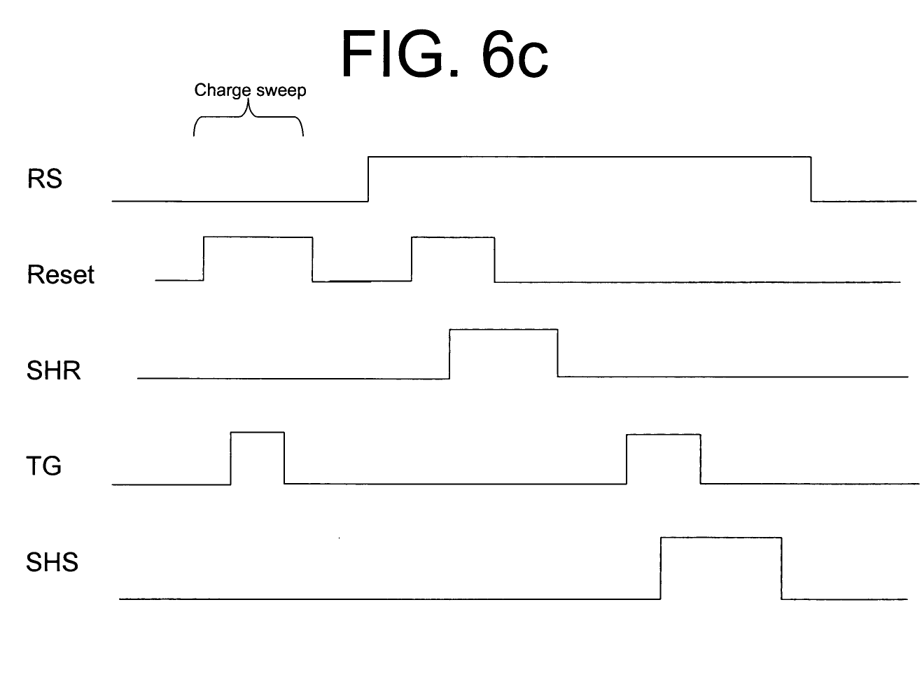

Now referring to the figures, FIG. 4 illustrates a top view of a pixel cell operated in accordance with an exemplary embodiment of the invention. FIG. 5 is a partially cut away view of the pixel of FIG. 4, therefore the structures of the FIG. 4 pixel cell will be described in reference to FIG. 5 where like reference numbers designate like elements. The operation of the pixel shown in FIGS. 4 and 5 will be described more fully below in connection with the timing diagrams of FIG. 6. As illustrated in FIG. 5, a photoconversion device 50 is illustratively formed in a p-type substrate 60 which also has a more heavily doped p-type well 61. The photoconversion device 50 is illustratively a photodiode and may be a p-n junction photodiode, a Schottky photodiode, or any other suitable photoconversion device. The remaining structures shown in FIG. 5 include a transfer transistor 26 and a reset transistor 28. Shallow trench isolation (STI) regions 55, used for isolating pixel cells, floating diffusion region 16 and a source/drain region 30 are also shown. A passivation layer 88 of, for example, BPSG, covers the pixel cell.

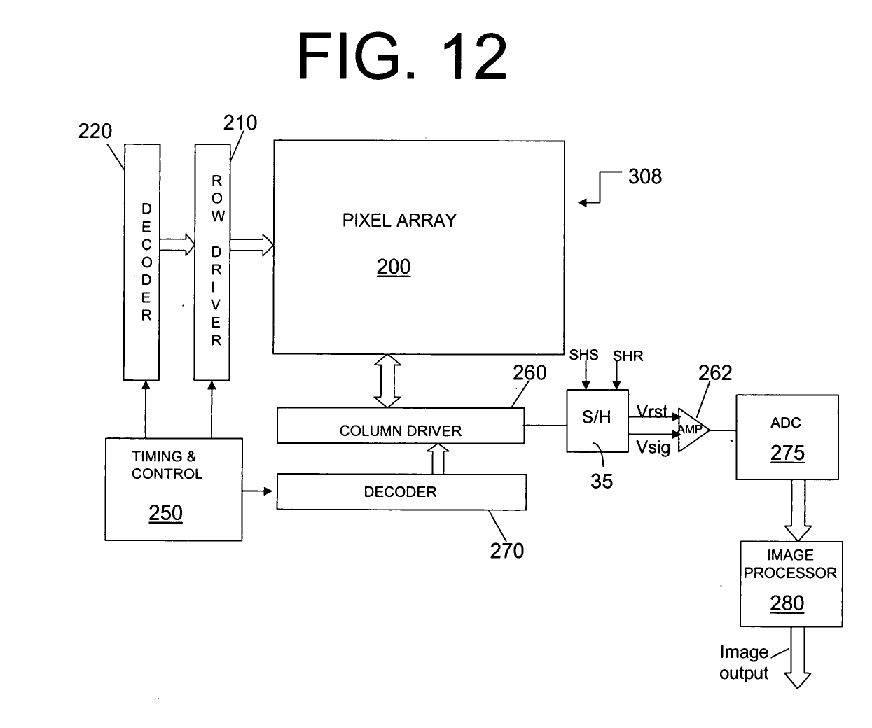

Floating diffusion region 16 is coupled to the gate of a source follower transistor 40, which receives the charge temporarily stored by the floating diffusion region 16 and provides an output signal based on the stored charge to a first source/drain terminal of a row select transistor 42. When the row select signal RS goes high, the signal produced by transistor 40 is coupled to the column line 31 where it is further processed by a sample/hold circuit 35 and subsequent downstream processing circuits (FIG. 12). Timing and control circuit 250 (FIG. 12) provides the timing signals RS, Reset, SHR, TG and SHS shown in FIGS. 6a-c which operate the FIG. 5 pixel circuit.

It should be noted that although FIG. 5 depicts a 4-transistor (4T) configuration with a transfer transistor 26, the invention can also be practiced with a pixel cell having a 5-transistor (5T) configuration, and also to pixel cells with other transistor configurations.

Turning to FIG. 6a, a timing diagram of a charge sweep operation conducted on the FIG. 5 pixel cell in order to reduce image lag is depicted in accordance with an exemplary embodiment of the invention. The row select transistor 42 is pulsed on by a row select signal RS. Reset transistor 28 is briefly turned on by a reset signal, Reset, thereby resetting floating diffusion region 16 to a predetermined voltage. The reset voltage Vᵣₛₜ produced by transistor 40 is sampled by reset sample and hold circuitry 35 activated by signal SHR. Charge accumulated in photodiode 50 is then transferred to floating diffusion region 16 by activating transfer transistor 26 with signal TG. The charge on the floating diffusion region 16 is applied to the gate of source follower transistor 40 which produces an output signal V_{sig}, which is subsequently sampled by signal sample and hold circuitry activated by signal SHS. Thus, sample and hold circuit 35 stores values for Vᵣₛₜ and V_{sjg} for subsequent processing.

After the signal V_{sig} is sampled by the signal sample and hold circuit 35, timing and control circuit 250 (FIG. 12) again pulses the reset transistor 28 and transfer transistor 26 to turn on substantially simultaneously. There is no requirement regarding the Reset or TG pulse widths or their relative turn-on or turn-off times. The only requirement is that at some point in time both transistors are simultaneously on. There is also no requirement on the RS pulse for the charge sweep operation. The TG and Reset pulses may be turned on while RS is on (FIG. 6a) or off (FIGS. 6b and 6c).

FIG. 6b shows a second timing embodiment. The timing according to FIG. 6b has a substantially similar operation to that described above in connection with FIG. 6a, with the exception of a shorter RS period. In the embodiment of FIG. 6b, the charge sweep operation is performed after the RS pulse is turned off.

The timing embodiment shown in FIG. 6c operates by reading out all rows before the next integration period. At the end of this readout of the entire array, Reset and TG are turned on. This can be accomplished by either turning on Reset and TG for all rows in the array or turning on Reset and TG substantially simultaneously row by row until the charge sweep operation is completed for all rows in the array.

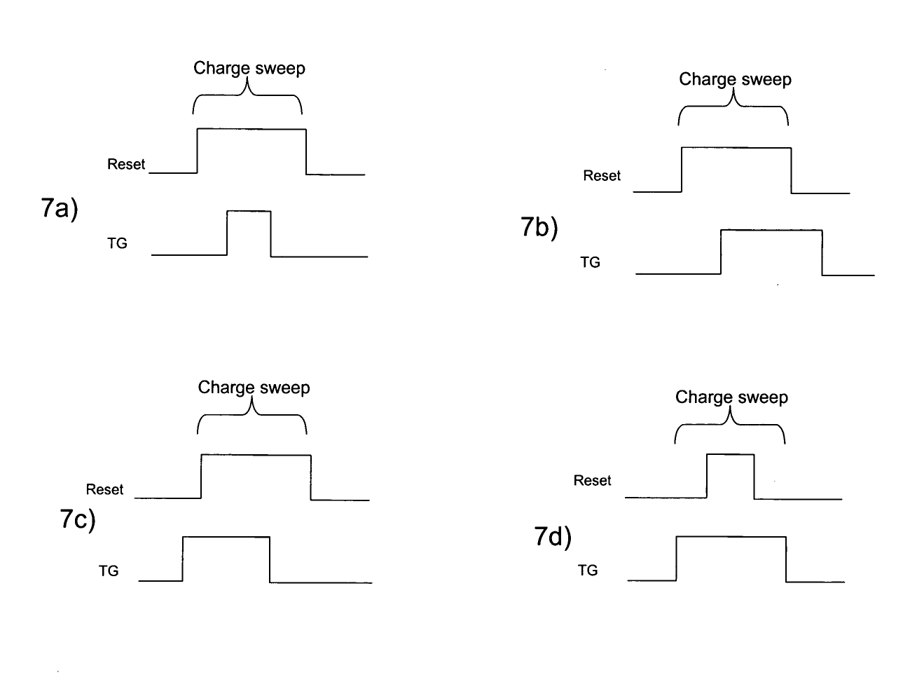

“Substantially simultaneously” is defined to mean that at some time during the second reset pulse the TG is pulsed on. Both pulses do not need to be turned on or off at nearly the same time. FIGS. 7a-d show embodiments of the Reset and TG activation. Only the Reset and TG pulses are shown, but it should be understood that these pulses operate within the timing embodiments shown in FIGS. 6a-c and other embodiments of the invention. The substantially simultaneous activation of reset transistor 28 and transfer transistor 26 after readout of V_{sig} serves to sweep residual charge out of the photodiode 50 and floating diffusion region 16 before the next integration period, thereby reducing image lag. The method described above is repeated for subsequent frames of the same pixel and also for other pixels of the imaging device.

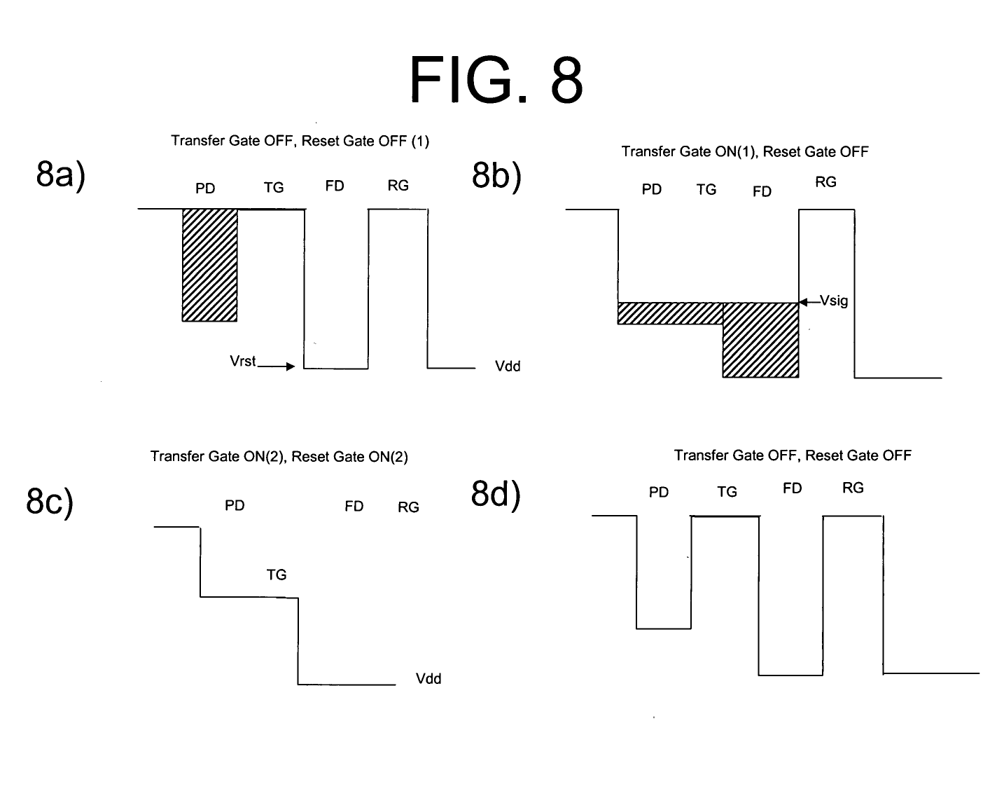

FIG. 8 shows several potential energy diagrams of the FIG. 5 pixel cell under different operating conditions as the method described above with reference to FIGS. 6a-c is performed. FIG. 8a, for example, shows the potential energy of the FIG. 5 pixel cell when the reset transistor 28 is turned on for a first time (1) and the transfer transistor 26 is turned off at the start of an integration period. The photodiode 50 has been reset and as shown in FIG. 8a, the photodiode 50 is filled (shaded area) with charge V_{sig} upon exposure to light. In FIG. 8b, the transfer transistor 26 is turned on for a first time (1) during this integration period, which allows charge to flow from the photodiode 50 to the floating diffusion region 16. The reset transistor 28 is turned off in FIG. 8b.

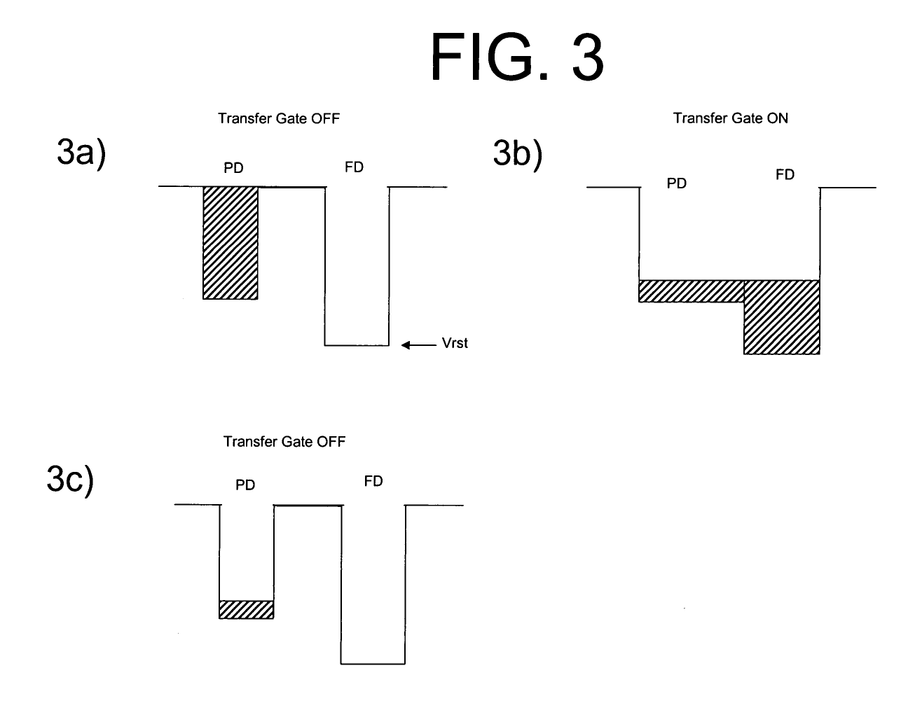

The potential energy diagrams shown in FIG. 8a and FIG. 8b are similar to those described above in relation to FIG. 3. However, FIG. 8c shows a potential state according to the method of the invention, in which after V_{sig} is readout and captured by the signal sample/hold circuit 35, the transfer transistor 26 and reset transistor 28 are turned on again at substantially the same time for a second time (2). The operation, as illustrated in FIG. 8c, allows charge to be swept out of the floating diffusion region 16 and photodiode 50. Since there is no charge remaining in the subsequent frame (FIG. 8d), image lag is substantially reduced.

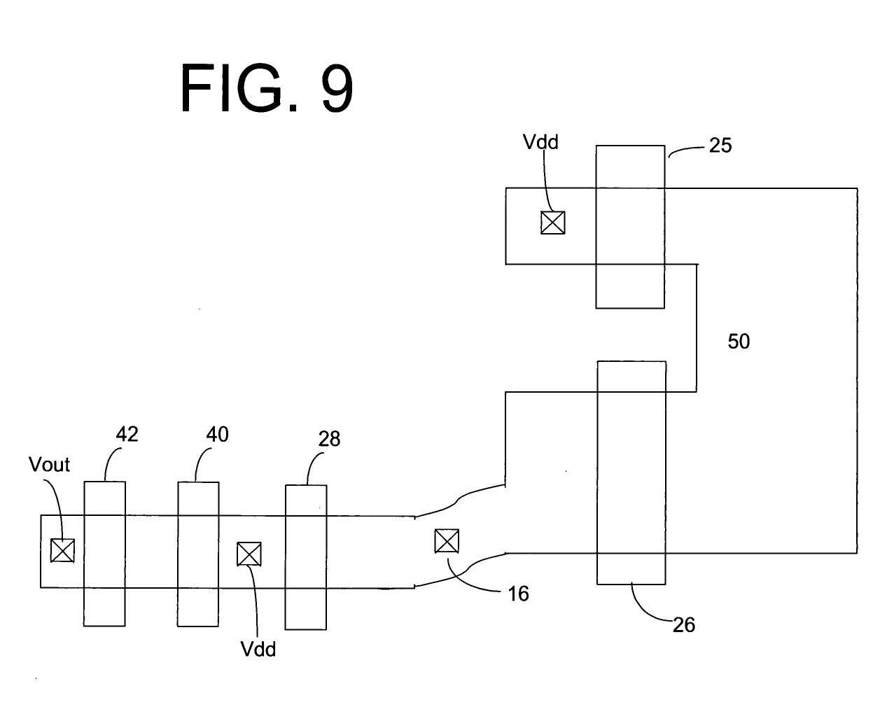

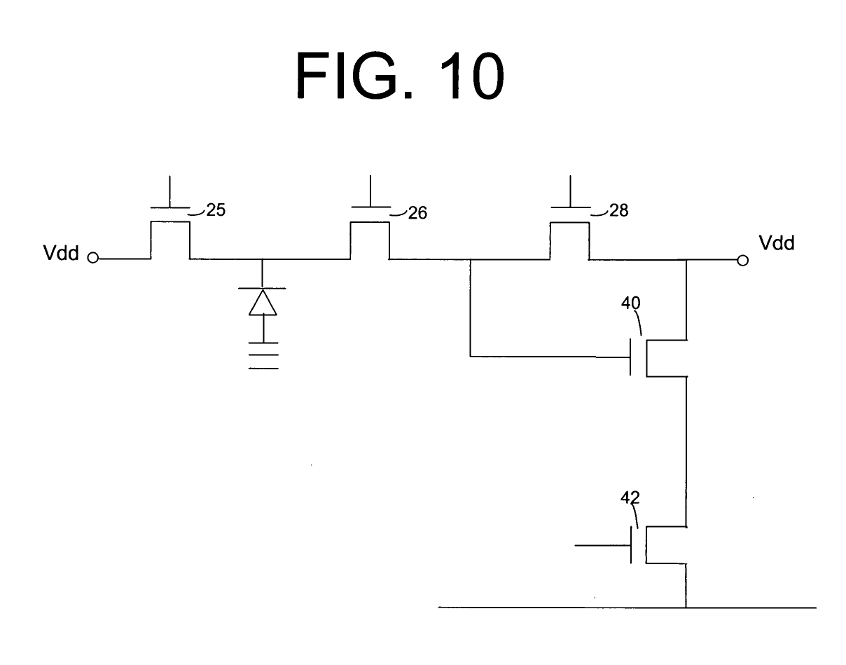

Another embodiment of the invention is shown in FIGS. 9-11, which depict the charge sweep operation for a 5T imager. The embodiment of FIGS. 9-11 employs electrical access to the photosensitive element (e.g., photodiode, photoconductor or photogate). FIG. 9 shows a top view of an exemplary 5T pixel and FIG. 10 shows a circuit diagram of an exemplary 5T pixel according to the invention. The pixel shown in FIGS. 9 and 10 is similar to the pixel shown in FIGS. 4 and 5 where like reference numbers denote like elements, with the exception of an additional transistor 25. There is an electrical connection between photodiode 50 and a supply voltage (for example, V_{dd}) through transistor 25. Transistor 25 can be a high dynamic range (HDR) transistor, global shutter or an anti-blooming transistor, to name a few examples. An exemplary HDR transistor 25 operates by holding the HDR transistor to a small positive DC voltage, VDC. This positive DC voltage, VDC, puts a break in the light versus voltage transfer curve thereby extending the dynamic range of the sensor. The HDR transistor also gives antiblooming protection during imaging, allowing excess collected charge to drain to Vdd through the “slightly on” HDR transitor.

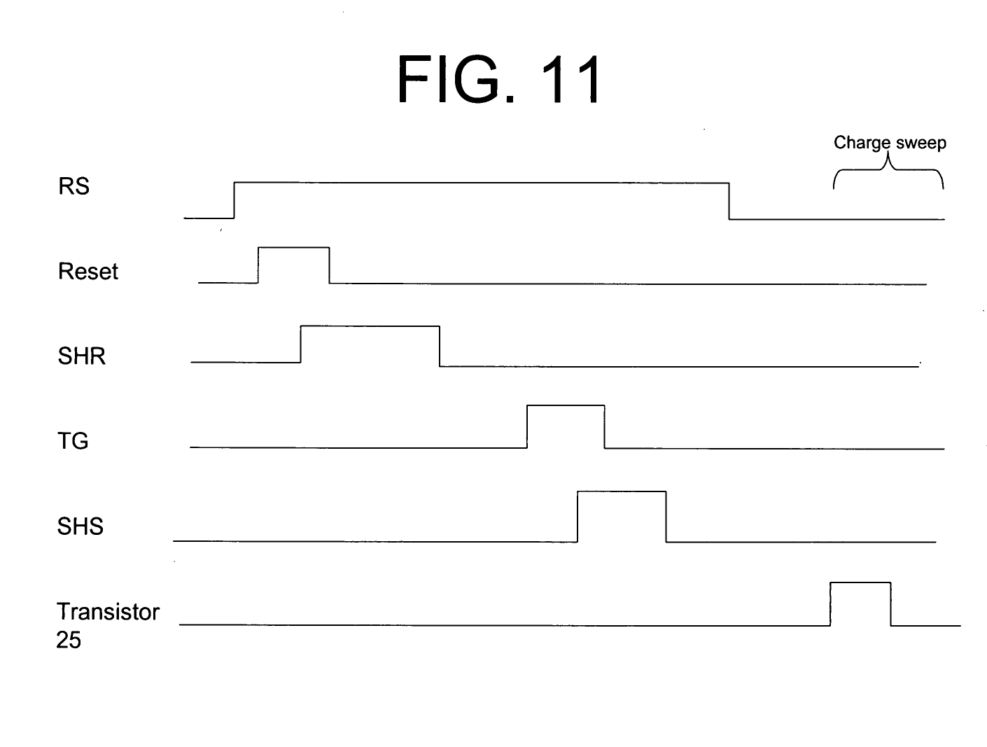

In the present embodiment shown in FIG. 11, only one transistor is turned on to conduct a charge sweep operation. In this timing embodiment, the Reset and TG are only turned on once, as in the operation shown in FIG. 3. In the exemplary timing embodiment shown in FIG. 11, transistor 25 is activated to perform a charge sweep operation. The timing of FIG. 11 differs from that of FIG. 3 because transistor 25 is turned on after V_{sig} is stored to perform a charge sweep operation according to the invention. The electrical path from supply voltage (V_{dd}) to the photodiode 50 allows residual charge to be swept from the photodiode 50 to supply voltage V_{dd} when transistor 25 is activated.

FIG. 12 illustrates a block diagram of an exemplary CMOS imager device 308 having a pixel array 200 with each pixel cell being constructed and operated as described above in connection with FIGS. 4-11. Pixel array 200 comprises a plurality of pixels arranged in a predetermined number of columns and rows (not shown). The pixels of each row in array 200 are all turned on at the same time by a row select line, and the pixels of each column are selectively output by respective column select lines. A plurality of row and column lines are provided for the entire array 200. The row lines are selectively activated by a row driver 210 in response to row address decoder 220. The column select lines are selectively activated by a column driver 260 in response to column address decoder 270. Thus, a row and column address is provided for each pixel.

The CMOS imager of FIG. 12 is operated by the timing and control circuit 250, which controls address decoders 220, 270 for selecting the appropriate row and column lines for pixel readout. The control circuit 250 also controls the row and column driver circuitry 210, 260 such that these apply driving voltages to the drive transistors of the selected row and column lines. The pixel column signals, Vᵣₛₜ and V_{sig}, are read by a sample and hold circuit 35 associated with the column driver 260. A differential signal (Vᵣₛₜ-V_{sig}) is produced by differential amplifier 262 for each pixel which is digitized by analog to digital converter 275 (ADC). The ADC 275 supplies the digitized pixel signals to an image processor 280 which forms a digital image. Alternatively, the differential signal Vrst-Vsig can be amplified as a differential signal and the amplified differential signal can be digitized by a differential analog to digital converter which provides the digitized signal to image processor 280.

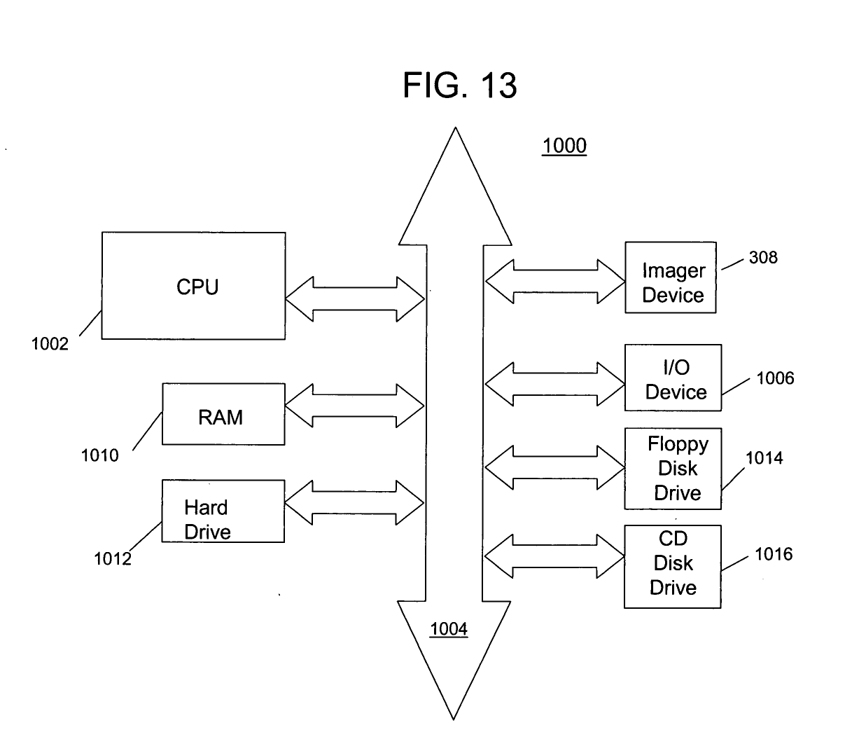

FIG. 13 depicts system 1000, which includes imager device 308, for example, as illustrated in FIG. 12 containing a pixel array with pixels operating in accordance with the exemplary embodiments described herein. Processor based systems exemplify systems of digital circuits that could include an imager device 308. Examples of processor based systems include, without limitation, computer systems, camera systems, scanners, machine vision systems, vehicle navigation systems, video telephones, surveillance systems, auto focus systems and others.

System 1000 includes an imager device 308 having the overall configuration depicted in FIG. 12 with pixels of array 200 constructed and operated in accordance with the exemplary embodiments of the invention. System 1000 includes a processor 1002 having a central processing unit (CPU) that communicates with various devices over a bus 1004. Some of the devices connected to the bus 1004 provide communication into and out of the system 1000; an input/output (I/O) device 1006 and imager device 308 are examples of such communication devices. Other devices connected to the bus 1004 provide memory, illustratively including a random access memory (RAM) 1010, hard drive 1012, and one or more peripheral memory devices such as a floppy disk drive 1014 and compact disk (CD) drive 1016. The imager device 308 may receive control or other data from CPU 1002 or other components of system 1000. The imager device 308 may, in turn, provide signals defining images to processor 1002 for image processing, or other image handling operations.

As described above, it is desirable to reduce image lag experienced in a pixel cell of an imager. Exemplary embodiments of the present invention have been described in which image lag is reduced using a charge sweep operation.

While the invention has been described in detail in connection with preferred embodiments known at the time, it should be readily understood that the invention is not limited to the disclosed embodiments. Rather, the invention can be modified to incorporate any number of variations, alterations, substitutions or equivalent arrangements not heretofore described, but which are commensurate with the spirit and scope of the invention. Accordingly, the invention is not limited by the foregoing description or drawings, but is only limited by the scope of the appended claims.

1. A method for operating a pixel cell of an imager, the method comprising:
accumulating charge at a photoconversion device during an integration period;
storing accumulated charge from said photoconversion device at a charge collection region;
reading out said charge from said charge collection region; and
removing residual charge remaining in said photoconversion device prior to a subsequent integration period.

2. The method of claim 1, wherein said act of removing comprises activating at least one of a reset transistor and a transfer transistor to couple said photoconversion device to a potential prior to said subsequent integration period.

3. The method of claim 2, wherein said reset transistor and said transfer transistor are activated substantially simultaneously.

4. The method of claim 3, wherein said substantially simultaneous activation of said reset transistor and said transfer transistor occurs after said act of reading out said charge.

5. The method of claim 1, wherein said act of transferring comprises transferring charge from said photoconversion device to a floating diffusion region.

6. The method of claim 5, wherein said act of storing charge comprises transferring said charge to said floating diffusion region via said transfer transistor.

7. The method of claim 1, wherein said act of transferring comprises transferring charge from said photoconversion device to a supply voltage Vdd.

8. The method of claim 1, wherein said act of reading out comprises reading out said charge with a transistor.

9. The method of claim 1, wherein the pixel cell is at least one of a five transistor (5T) pixel, a six transistor pixel (6T) or a seven transistor pixel (7T).

10. The method of claim 9, wherein the act of removing comprises activating a transistor electrically connected to said photoconversion device wherein said transistor includes at least one of a global shutter, antiblooming device or high dynamic range transistor (HDR).

11. The method of claim 10, wherein the act of activating said transistor allows residual charge to move from said photoconversion device to a supply voltage (V_{dd}).

12. The method of claim 1, wherein the imager is a CMOS imager.

13. The method of claim 12, wherein the CMOS imager comprises four transistor (4T) pixels.

14. The method of claim 12, wherein the CMOS imager comprises six transistor (6T) pixels.

15. The method of claim 12, wherein the CMOS imager comprises seven transistor (7T) pixels.

16. The method of claim 1, wherein said photoconversion device is a photodiode.

17. The method of claim 1, wherein said photoconversion device is a photogate.

18. The method of claim 1, wherein said photoconversion device is a photoconductor.

19. A method for operating a pixel cell of an imager, the method comprising:
resetting a charge collection region with a reset transistor during a reset period;
accumulating charge at a photoconversion device during an integration period;
storing accumulated charge from said photoconversion device at said charge collection region via a transfer transistor;
reading out said charge from said charge collection region to a sample and hold circuit; and
removing residual charge remaining in said photoconversion device after said charge storage at said charge collection region, wherein said act of removing comprises activating said reset transistor and said transfer transistor prior to a subsequent integration period.

20. The method of claim 19, wherein said act of removing comprises activating said reset transistor and said transfer transistor substantially simultaneously.

21. The method of claim 19, wherein said substantially simultaneous activation of said reset transistor and said transfer transistor occurs after said act of reading out said charge.

22. The method of claim 19, wherein said act of transferring comprises transferring charge from said photoconversion device to a supply voltage Vdd.

23. The method of claim 19, wherein the imager is a CMOS imager.

24. The method of claim 23, wherein the CMOS imager comprises one of a four transistor, five transistor, six transistor or seven transistor pixel architecture.

25. The method of claim 19, wherein said photoconversion device is a photodiode.

26. The method of claim 19, wherein said photoconversion device is a photogate.

27. The method of claim 19, wherein said photoconversion device is a photoconductor.

28. A method for operating a pixel cell of an imager, the method comprising:
resetting a charge collection region with a reset transistor during a reset period;
accumulating charge at a photoconversion device during an integration period;
storing accumulated charge from said photoconversion device at said charge collection region via a transfer transistor;
reading out said charge from said charge collection region to a sample and hold circuit; and
removing residual charge remaining in said photoconversion device after said charge storage at said charge collection region, wherein said act of removing comprises activating a transistor electrically connected to said photoconversion device prior to a subsequent integration period.

29. The method of claim 28, wherein the pixel cell has at least one of a four transistor (4T), five transistor (5T), six transistor (6T) or seven transistor (7T) pixel architecture.

30. The method of claim 28, wherein the act of removing comprises activating said transistor electrically connected to said photoconversion device wherein said transistor includes least one of a global shutter, antiblooming device or high dynamic range transistor (HDR).

31. The method of claim 28, wherein the act of activating said transistor allows residual charge to move from said photoconversion device to a supply voltage (V_{dd}).

32. The method of claim 28, wherein said act of transferring comprises transferring charge from said photoconversion device to a supply voltage Vdd.

33. The method of claim 28, wherein the imager is a CMOS imager.

34. The method of claim 33, wherein the pixel cell is a six transistor (6T) pixel.

35. The method of claim 33, wherein the pixel cell is a seven transistor (7T) pixel.

36. The method of claim 28, wherein said photoconversion device is a photodiode.

37. The method of claim 28, wherein said photoconversion device is a photogate.

38. The method of claim 28, wherein said photoconversion device is a photoconductor.

39. An imaging device, comprising:
a photoconversion device for accumulating charge during an integration period;
a charge collection region coupled to said photoconversion device for storing charge accumulated at said photoconversion device; and
a readout portion coupled to said charge collection region for reading out said charge from said charge collection region, and wherein said imaging device is configured to remove residual charge from said photoconversion device prior to a subsequent integration period.

40. The imaging device of claim 39, further comprising a controller for controlling removal of said residual charge.

41. The imaging device of claim 40, further comprising a reset transistor for resetting said charge collection region to a predetermined state and a transfer transistor for transferring charge from said photoconversion device to said charge collection region, wherein said controller is configured to activate said reset transistor and transfer transistor prior to said subsequent integration period.

42. The imaging device of claim 39, wherein said controller is configured to activate said reset transistor and said transfer transistor substantially simultaneously following said charge readout.

43. The imaging device of claim 39, wherein said imaging device is a CMOS imager.

44. The imaging device of claim 39, wherein said imaging device comprises a four transistor pixel cell.

45. The imaging device of claim 39, wherein said imaging device comprises a five transistor pixel cell.

46. The imaging device of claim 45, further comprising a transistor electrically connected to said photoconversion device.

47. The imaging device of claim 46, wherein said transistor includes at least one of a global shutter, antiblooming device or high dynamic range transistor (HDR).

48. The imaging device of claim 46, wherein said transistor electrically connected to said photoconversion device allows residual charge to move from said photoconversion device to a supply voltage (V_{dd}) when said transistor is activated.

49. The imaging device of claim 39, wherein said charge collection region comprises a floating diffusion region.

50. A processing system comprising:
a processor; and
an imaging device coupled to said processor, said imaging device comprising:
a photoconversion device for accumulating charge during an integration period;
a charge collection region coupled to said photoconversion device for storing charge accumulated at said photoconversion device; and
a readout portion coupled to said charge collection region for reading out said charge from said charge collection region, and wherein said imaging device is configured to remove residual charge from said photoconversion device prior to a subsequent integration period.

51. The system of claim 50, wherein said imaging device further comprises a controller for controlling removal of said residual charge.

52. The system of claim 51, wherein said controller is configured to activate a reset transistor and a transfer transistor prior to said subsequent integration period.

53. The system of claim 52, wherein said controller is configured to activate said reset transistor and said transfer transistor substantially simultaneously following said charge readout.

54. The system of claim 50, wherein said imaging device is a CMOS imager.

55. The system of claim 50, wherein said imaging device comprises a four transistor pixel cell.

56. The system of claim 50, wherein said imaging device comprises a five transistor pixel cell.

57. The system of claim 56, further comprising a transistor electrically connected to said photoconversion device.

58. The system of claim 57, wherein said transistor includes at least one of a global shutter, antiblooming device or high dynamic range transistor (HDR).

59. The system of claim 57, wherein said transistor electrically connected to said photoconversion device allows residual charge to move from said photoconversion device to a supply voltage (V_{dd}) when said transistor is activated.

60. The system of claim 50, wherein said charge collection region comprises a floating diffusion region.

61. An imager comprising:
an array of pixel sensor cells, said imager being configured to remove residual charge from a respective photoconversion device of each pixel sensor cell included in said imager after a respective signal voltage is readout of each pixel sensor cell and prior to a subsequent integration period for said pixel sensor cell.

62. The imager of claim 61, further comprising a controller for controlling the removal of said residual charge.

63. The imager of claim 62, further comprising a reset transistor and a transfer transistor within each pixel sensor cell and wherein said controller is configured to activate said reset transistor and said transfer transistor substantially simultaneously prior to said subsequent integration period.

64. The imager of claim 62, further comprising a transistor electrically connected to said photoconversion device and wherein said controller is configured to activate said transistor prior to said subsequent integration period.
